(19) United States
(12) Patent Application Publication
(10) Pub. No.: US 2016/0300737 A1
(43) Pub. Date: Oct. 13, 2016

(54) Airflow Control Device and Method of Adjusting the Same, Substrate Cleaning Device

(71) Applicants: BOE TECHNOLOGY GROUP CO., LTD., Beijing (CN); HEFEI XINSHENG OPTOELECTRONICS TECHNOLOGY CO., LTD., Hefei (CN)

(72) Inventors: Peng XU, Beijing (CN); Yong WANG, Beijing (CN); Yongkang QIAO, Beijing (CN); Gu YAO, Beijing (CN)

(21) Appl. No.: 15/083,470

(22) Filed: Mar. 29, 2016

(30) Foreign Application Priority Data
Apr. 7, 2015 (CN) 201510161262.0

(51) Int. Cl. H01L 21/67; H01L 21/677

(52) U.S. Cl. CPC H01L 21/67051; H01L 21/67742

(57) ABSTRACT

The present invention discloses an airflow control device and a method of adjusting the same, a substrate cleaning device. The airflow control device is provided in a cleaning chamber for cleaning a substrate, and includes a first cover, a second cover, a third cover and a fourth cover. The first cover and the third cover are provided face to face in the upper portion of the cleaning chamber, the second cover and the fourth cover are provided face to face in the lower portion of the cleaning chamber. The four covers form an airflow control space which accommodates a cleaning solution outlet. The space is used for keeping the strong airflow within the area under the outlet, such that shaking and deformation of the substrate due to the strong airflow are reduced to improve the efficiency of cleaning, and reduce the risk of fragmentation, and further lower the production cost.

### TECHNICAL FIELD

The present invention relates to the technical field of display, and particularly, to an airflow control device and a method of adjusting same, and a substrate cleaning device.

### BACKGROUND ART

Super High Pressure Micro Jet (referred to as HPMJ) is applied to cleaning process of a substrate such as glass in the prior art. A cleaning solution is pressurized to 3 MPa˜32.5 MPa, and jetted through a microporous nozzle having a pore size of hundreds of microns to form fine droplets with high flow rate to clean the substrate. The HPMJ technology increases the detergency of jetting, shortens the length of cleaning line, and saves cleaning space as well as the amount of deionized water (referred to as DI water).

### SUMMARY OF INVENTION

### Technical Problem

Recently, Active-Matrix Organic Light Emitting Diode (referred to as AMOLED) requires substrates having higher cleanliness. In early cleaning process, the pressure adopted in HPMJ is increased in order to achieve high cleanliness. However, the cleaning chamber is an approximate closed system, when negative pressure of exhaust is constant, increasing HPMJ pressure will inevitably cause the pressure in the cleaning chamber to gradually increase with time, which further causes airflow disturbance in the cleaning chamber. When influenced by a strong disordered airflow, a substrate that enters into the front of the HPMJ cleaning chamber will shake and deform severely, and even float above the transfer wheel. Details are shown in FIG. 11: the airflow below the cleaning solution outlet presents sector with a certain angle and spreads downward. The vertical airflow heading downward is reflected and spreads towards both sides when it encounters the bottom of the cleaning chamber. When the substrate enters into the chamber from left side, it will be impacted by a strong airflow heading upward and shake severely, even float above the transfer wheel during transferring. Therefore, the risk of fragmentation at this moment increases rapidly. Even if the substrate does not fragment, since it undergoes severe deformation, its life in processes of coating, transferring and so on will be shortened, thereby the excellent rate decreases. Therefore, the problem to be solved is how to ensure the substrate's life while ensuring the cleaning effect.

### Solution to Problem

In order to solve the above problem, the inventor proposes three schemes. Table 1 shows a comparison of schemes for solving the problem of shaking provided by the inventor. From table 1, it can be seen that, the scheme solving the problem by controlling the flow of the airflow in the cleaning chamber has the best effect, lower cost, and good feasibility.

TABLE 1

| | | Advantages and | |
|---|---|---|---|
| Scheme | Idea for solution | disadvantages | Cost |
| A | Increasing exhaust on | Need to increase | High |
| | factory side | the number | |
| | | of fan, high cost | |
| B | Controlling the | Low cost, good | Low |
| | flow of the airflow | feasibility | |
| | in the chamber | | |
| C | Increasing the number | Substrate is pressed so | Relatively |
| | of anti-shake hardware | that its life is shortened | high |

Namely, the present invention provides an airflow control device and a method of adjusting the same, and a substrate cleaning device, to solve the existing problem that the substrate shakes and deforms severely, even floats above the transfer wheel when the substrate enters into cleaning chamber.

Accordingly, the first aspect of the present invention provides an airflow control device disposed in a cleaning chamber for cleaning a substrate, said airflow control device includes a first airflow control cover, a second airflow control cover, a third airflow control cover, and a fourth airflow control cover (hereafter, referred to as first cover, second cover, third cover and fourth cover, respectively); said first cover and said third cover are disposed face to face in the upper portion of the cleaning chamber, and said second cover and said fourth cover are disposed face to face in the lower portion of the cleaning chamber, a first gap is formed between said first cover and said second cover, and a second gap is formed between said third cover and said fourth cover; said first cover, said second cover, said third cover and said fourth cover form an airflow control space which accommodates a cleaning solution outlet, said substrate enters into the airflow control space through said first gap, and leaves the airflow control space through said second gap.

Alternatively, the second aspect of the present invention is the airflow control device according to the first aspect, wherein, said first cover, said second cover, said third cover and said fourth cover are substantially perpendicular to the transfer direction of the substrate.

With the airflow control device described above, the strong airflow can be effectively kept in a small area under the cleaning solution outlet, which is the space surrounded by the covers and the wall of the cleaning chamber. Here, the strong airflow reflected by the bottom of the chamber can only spread parallelly through the gaps between upper and lower covers towards two sides. Thereby, the direction of the strong airflow is changed effectively, and the problem that the strong airflow impacts the substrate from a bottom-to-up direction is solved.

Alternatively, the third aspect of the present invention is the airflow control device according to the first aspect, wherein, it further includes an exhaust structure, said exhaust structure is connected with said airflow control space via a vent port, said vent port is disposed in said second cover or said fourth cover; said exhaust structure is used for reducing the pressure in said airflow control space.

With the exhaust structure described above, the pressure in the area surrounded by the covers can be reduced effectively, thereby the airflow control device can deal with a super high pressure cleaning having higher pressure.

Alternatively, the fourth aspect of the present invention is the airflow control device according to the first aspect, wherein,

a first support is disposed on said cleaning chamber, a first through hole is disposed in said first support, a first strip hole is disposed in said first cover, a first bolt is disposed in said first strip hole, said first bolt fixedly connects with said first through hole so that said first cover is fixed to said first support, said first strip hole is used for fixing said first bolt to different positions of said first strip hole so as to adjust the height of said first cover;

a second support is disposed on said cleaning chamber, a second through hole is disposed in said second support, a second strip hole is disposed in said second cover, a second bolt is disposed in said second strip hole, said second bolt fixedly connects with said second through hole so that said second cover is fixed to said second support, said second strip hole is used for fixing said second bolt to different positions of said second strip hole so as to adjust the height of said second cover;

a third support is disposed on top of said cleaning chamber, a third through hole is disposed in said third support, a third strip hole is disposed in said third cover, a third bolt is disposed in said third strip hole, said third bolt fixedly connects with said third through hole so that said third cover is fixed to said third support, said third strip hole is used for fixing said third bolt to different positions of said third strip hole so as to adjust the height of said third cover;

a fourth support is disposed on top of said cleaning chamber, a fourth through hole is disposed in said fourth support, a fourth strip hole is disposed in said fourth cover, a fourth bolt is disposed in said fourth strip hole, said fourth bolt fixedly connects with said fourth through hole so that said fourth cover is fixed to said fourth support, said fourth strip hole is used for fixing said fourth bolt to different positions of said fourth strip hole so as to adjust the height of said fourth cover.

Alternatively, the fifth aspect of the present invention is the airflow control device according to the fourth aspect, wherein,

the numbers of said first strip hole, first through hole and first bolt are three respectively, said three first strip holes are arranged parallel to each other;

the numbers of said second strip hole, second through hole and second bolt are three respectively, said three second strip holes are arranged parallel to each other;

the numbers of said third strip hole, third through hole and third bolt are three respectively, said three third strip holes are arranged parallel to each other;

the numbers of said fourth strip hole, fourth through hole and fourth bolt are three respectively, said three fourth strip holes are arranged parallel to each other.

Alternatively, the sixth aspect of the present invention is the airflow control device according to the fourth aspect, wherein,

it further includes a first motor, a first rack, a second motor, a second rack, a third motor, a third rack, a fourth motor and a fourth rack,

said first motor is fixedly disposed outside said cleaning chamber, said first rack fixedly connects with said first cover, a gear matching with said first rack is disposed on the rotary shaft of said first motor so as to drive said first rack to move vertically;

said second motor is fixedly disposed outside said cleaning chamber, said second rack fixedly connects with said second cover, a gear matching with said second rack is disposed on the rotary shaft of said second motor so as to drive said second rack to move vertically;

said third motor is fixedly disposed outside said cleaning chamber, said third rack fixedly connects with said third cover, a gear matching with said third rack is disposed on the rotary shaft of said third motor so as to drive said third rack to move vertically;

said fourth motor is fixedly disposed outside said cleaning chamber, said fourth rack fixedly connects with said fourth cover, a gear matching with said fourth rack is disposed on the rotary shaft of said fourth motor so as to drive said fourth rack to move vertically.

With the above motor and related members, automatic adjustment can be achieved by motor control. Compared to manual adjustment, there is no need to open the chamber for operating every time, so that the adjusting process can be simplified, and the adjustment accuracy can be improved. However, the cost becomes higher since the motor and other mechanical components are added.

Alternatively, the seventh aspect of the present invention is the airflow control device according to the fourth aspect, wherein, accurate graduated scales are amounted on both sides of said covers.

Alternatively, the eighth aspect of the present invention is the airflow control device according to the fourth aspect, wherein, the size of the gap is calculated as follow:

Cover GAP=Gap0+H1+H2

wherein, Cover GAP represents the size of the gap, Gap0 represents the size of the gap when the bolt of the cover above the substrate is locked at the uppermost position of a corresponding strip hole, and the size of the gap when the bolt of the cover below the substrate is fixed at the lowermost position of a corresponding strip hole, H1 represents a height difference between the position of the bolt in the cover above the substrate after adjusting the cover and the uppermost position of the bolt, H2 represents a height difference between the position of the bolt in the cover below the substrate after adjusting the cover and the lowermost position of the bolt.

Alternatively, the ninth aspect of the present invention is the airflow control device according to the first aspect, wherein, the size of said first gap is not less than 10 mm, the size of said second gap is not less than 10 mm.

By providing graduated scales, the amount of vertical movement of the covers can be read to calculate the sizes of the gaps accurately and conveniently later. Furthermore, since the transferred substrate shakes inevitably when undergoes super high pressure cleaning, the sizes of said first gap and said second gap are set to not less than 10 mm respectively in view of safety concerns.

Alternatively, the tenth aspect of the present invention is the airflow control device according to the ninth aspect, wherein, the distance between said first cover and the substrate plane is 1 cm-10 cm, the distance between said second cover and the substrate plane is 1 cm-10 cm, the distance between said third cover and the substrate plane is 1 cm-10 cm, the distance between said fourth cover and the substrate plane is 1 cm-10 cm.

The eleventh aspect of the present invention provides a substrate cleaning device including a cleaning chamber and the airflow control device according to any one of the first aspect to the ninth aspect.

Alternatively, the twelfth aspect is the substrate cleaning device according to the eleventh aspect, wherein,

it further includes a transfer wheel, a first pinch roller and a second pinch roller, said first pinch roller includes a first upper pinch roller and a first lower pinch roller disposed opposite to each other, said second pinch roller includes a second upper pinch roller and a second lower pinch roller disposed opposite to each other; said transfer wheel is disposed in the airflow control chamber, said first pinch roller is disposed on one side of said airflow control space, said second pinch roller is disposed on the other side of said airflow control space; when driven by the transfer wheel, said substrate enters into the airflow control space through the gap between said first upper pinch roller and said first lower pinch roller, and then leaves the airflow control space through the gap between said second upper pinch roller and said second lower pinch roller;

said transfer wheel is used for providing transferring power to said substrate;

said first pinch roller is used for clamping said substrate;

said second pinch roller is used for clamping said substrate.

The substrate cleaning device of the present invention can avoid effectively the disturbance from strong airflow during transfer process and the damage to the substrate itself, thereby the risk of fragmentation can be greatly reduced.

The thirteenth aspect of the present invention provides a method of adjusting an airflow control device, which is used on the airflow control device according to any one of the first aspect to the tenth aspect, the method includes:

turning off said airflow control device, stopping transferring the substrate, stopping jetting cleaning solution to said substrate;

adjusting the sizes of said first gap and said second gap;

turning on said airflow control device, starting said first gap and said second gap transferring the substrate, starting said cleaning solution outlet jetting cleaning solution to said substrate;

judging whether said substrate shakes during cleaning and transferring process;

repeating said step of turning off said airflow control device if the judgment is that said substrate shakes during cleaning and transferring process.

Alternatively, the fourteenth aspect of the present invention is the method of adjusting an airflow control device according to the thirteenth aspect, wherein,

a first support is disposed on said cleaning chamber, a first through hole is disposed in said first support, a first strip hole is disposed in said first cover, a first bolt is disposed in said first strip hole, said first bolt fixedly connects with said first through hole so that said first cover is fixed to said first support, said first strip hole is used for fixing said first bolt to different positions of said first strip hole so as to adjust the height of said first cover;

a second support is disposed on said cleaning chamber, a second through hole is disposed in said second support, a second strip hole is disposed in said second cover, a second bolt is disposed in said second strip hole, said second bolt fixedly connects with said second through hole so that said second cover is fixed to said second support, said second strip hole is used for fixing said second bolt to different positions of said second strip hole so as to adjust the height of said second cover;

a third support is disposed on said cleaning chamber, a third through hole is disposed in said third support, a third strip hole is disposed in said third cover, a third bolt is disposed in said third strip hole, said third bolt fixedly connects with said third through hole so that said third cover is fixed to said third support, said third strip hole is used for fixing said third bolt to different positions of said third strip hole so as to adjust the height of said third cover;

a fourth support is disposed on top of said cleaning chamber, a fourth through hole is disposed in said fourth support, a fourth strip hole is disposed in said fourth cover, a fourth bolt is disposed in said fourth strip hole, said fourth bolt fixedly connects with said fourth through hole so that said fourth cover is fixed to said fourth support, said fourth strip hole is used for fixing said fourth bolt to different positions of said fourth strip hole so as to adjust the height of said fourth cover;

the step of adjusting the sizes of said first gap and said second gap includes:

adjusting said first bolt, said second bolt, said third bolt and said fourth bolt so that said first cover, said second cover, said third cover and said fourth cover can move vertically;

moving said first cover, said second cover, said third cover and said fourth cover to predetermined positions;

adjusting said first bolt, said second bolt, said third bolt and said fourth bolt to fix said first cover, said second cover, said third cover and said fourth cover.

Alternatively, the fifteenth aspect of the present invention is the method of adjusting an airflow control device according to the thirteenth aspect, wherein, said airflow control device further includes a first motor, a first rack, a second motor, a second rack, a third motor, a third rack, a fourth motor and a fourth rack;

said first motor is fixedly disposed outside said cleaning chamber, said first rack fixedly connects with said first cover, a gear matching with said first rack is disposed on the rotary shaft of said first motor so as to drive said first rack to move vertically;

said second motor is fixedly disposed outside said cleaning chamber, said second rack fixedly connects with said second cover, a gear matching with said second rack is disposed on the rotary shaft of said second motor so as to drive said second rack to move vertically;

said third motor is fixedly disposed outside said cleaning chamber, said third rack fixedly connects with said third cover, a gear matching with said third rack is disposed on the rotary shaft of said third motor so as to drive said third rack to move vertically;

said fourth motor is fixedly disposed outside said cleaning chamber, said fourth rack fixedly connects with said fourth cover, a gear matching with said fourth rack is disposed on the rotary shaft of said fourth motor so as to drive said fourth rack to move vertically;

the step of adjusting the sizes of said first gap and said second gap includes:

turning on said first motor, said second motor, said third motor and said fourth motor;

controlling the rotation direction and rotation amount of said first motor, said second motor, said third motor and said fourth motor to move said first cover, said second cover, said third cover and said fourth cover to predetermined positions;

turning off said first motor, said second motor, said third motor and said fourth motor.

Alternatively, the sixteenth aspect of the present invention is the method of adjusting an airflow control device according to the thirteenth aspect, wherein, said airflow control device further includes an exhaust structure, said exhaust structure is connected with said airflow control space via a vent port, said vent port is disposed in said second cover or said fourth cover;

the adjusting method further includes:

turning on said exhaust structure if it is judged that said substrate shakes during cleaning and transferring process when the sizes of said first gap and said second gap are adjusted to a minimum value;

controlling said exhaust structure to reduce the pressure in said airflow control space in a predetermined exhaust amount;

judging whether said substrate shakes during cleaning and transferring process;

repeating said step of controlling said exhaust structure reducing the pressure in said airflow control space with a predetermined exhaust amount if the judgment is that said substrate shakes during cleaning and transferring process.

According to the above method for adjusting an airflow control device of the present invention, it can be ensured that the airflow spreading through the cover gaps will not affect the transfer of the substrate, thereby solve the problem that the substrate shakes and deforms severely on the transfer wheel, even floats above the transfer wheel.

### Advantageous Effects of Invention

According to the airflow control device and the method of adjusting the same, and the substrate cleaning device provided by the present invention, the shaking and deformation of the substrate due to a strong airflow can be reduced, the effect of cleaning is improved, the risk of fragmentation is reduced, and thereby the production cost is reduced.

### DESCRIPTION OF THE DRAWINGS

FIG. 1 is a schematic view of the structure of an airflow control device provided in Example 1 of the present invention;

FIG. 2 is a front view of a first cover or a third cover in the airflow control device shown in FIG. 1;

FIG. 3 is a side view of the first cover or the third cover shown in FIG. 2;

FIG. 4 is a front view of another first cover or third cover in the airflow control device shown in FIG. 1;

FIG. 5 is a side view of the first cover or the third cover shown in FIG. 4;

FIG. 6 is an enlarged view of the structure of part Q shown in FIG. 5;

FIG. 7 is a schematic view of the structure of a substrate cleaning device provided in Example 2 of the present invention;

FIG. 8 is a flow chart of a method for adjusting an airflow control device provided in Example 3 of the present invention;

FIG. 9 is a structure diagram of the first cover and second cover, or the third cover and fourth cover in Example 3;

FIG. 10 is another structure diagram of the first cover and second cover, or the third cover and fourth cover in Example 3;

FIG. 11 is a schematic view of the structure of a cleaning chamber before the airflow control device of the present invention is installed.

### DESCRIPTION OF EMBODIMENTS

Hereafter, the airflow control device and the method of adjusting the same, and the substrate cleaning device provided by the present invention will be described in more detail with reference to the accompanying figures, so that a person skilled in the art can get a better understanding of the technical solutions provided by the invention.

### Example 1

FIG. 1 is a schematic view of the structure of an airflow control device provided in Example 1 of the present invention. As shown in FIG. 1, the airflow control device includes four covers, that is, a first cover 101, a second cover 102, a third cover 103 and a fourth cover 104. The first cover 101 and the third cover 103 are disposed face to face in the upper portion of the cleaning chamber, the second cover 102 and the fourth cover 104 are disposed face to face in the lower portion of the cleaning chamber, so that the first cover 101, the second cover 102, the third cover 103 and the fourth cover 104 form an airflow control space which accommodates a cleaning solution outlet 105. The airflow control space can effectively keep the strong airflow in an area under the cleaning solution outlet 105, which is the space surrounded by four covers. The direction of the arrows in the airflow control space is the direction of airflow. A first gap is formed between the first cover 101 and the second cover 102, and a second gap is formed between the third cover 103 and the fourth cover 104. A substrate 202 is transferred through the first gap and the second gap, and a cleaning solution is jetted to the substrate 202 by the cleaning solution outlet 105. Here, the strong airflow reflected by the bottom of the chamber can only spread parallelly through the gaps between upper and lower covers towards two sides. Thereby, the direction of the strong airflow is changed effectively, and solve the problem that the strong airflow impacts substrate from a bottom-to-up direction, thus the shaking and deformation of the substrate due to the strong airflow are reduced, the effect of cleaning is improved, the risk of fragmentation is reduced, and thereby the production cost is reduced.

Referring to FIG. 1, when the substrate 202 enters into the place just below the cleaning solution outlet 105 along the direction of arrow on the left side of FIG. 1 to super high pressure cleaning, a transfer wheel 106 is used for providing transferring power to the substrate 202, a first pinch roller (Double Roller) is used for clamping the substrate 202, and a second pinch roller (Double Roller) is used for clamping the substrate 202, too. The first pinch roller includes a first upper pinch roller 107 and a first lower pinch roller 108 disposed opposite to each other, the second pinch roller includes a second upper pinch roller 109 and a second lower pinch roller 201 disposed opposite to each other. The first pinch roller is disposed on one side of said airflow control space, and the second pinch roller is disposed on the other side of said airflow control space. A sensor 203 is disposed below the substrate 202, the sensor 203 is used for detecting shaking amplitude of the substrate 202, so that an operator can know about the shaking all the time. When the substrate 202 shakes and deforms severely on the transfer wheel, even floats above the transfer wheel, the sensor 203 will glitter. Then the first pinch roller and the second pinch roller can reduce the shaking amplitude of the substrate, avoid effectively the disturbance from the strong airflow during transfer process and the damage to the substrate itself, thereby the risk of fragmentation can be greatly reduced.

It should be emphasized that, the sizes of the first gap and the second gap directly decide flow rate and direction of the airflow spreading from the airflow control space. The first gap and the second gap should be adjusted with respect to various super high pressure, in order to ensure that the airflow spreading through the gaps would not affect the transfer of the substrate. The size of the first gap is referred to Gap A, the size of the second gap is referred to Gap B. In practical application and adjustment, the value of Gap A is not necessarily the same as the that of Gap B, it depends on actual conditions.

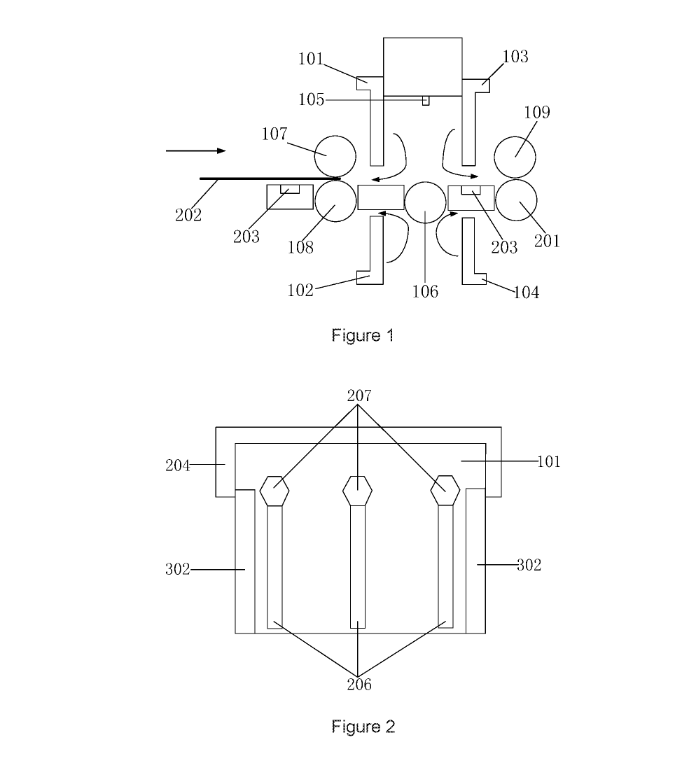

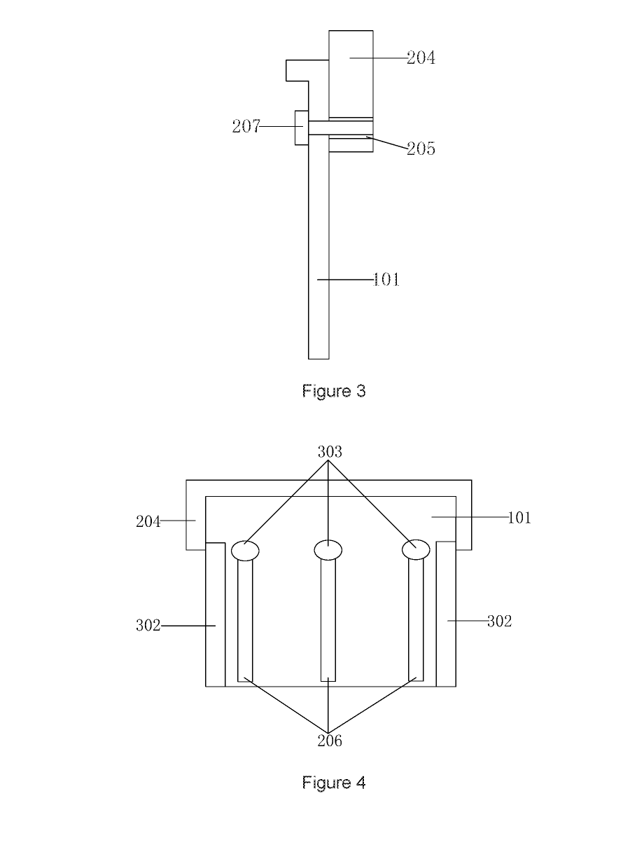

FIG. 2 is a front view of the first cover or the third cover in the airflow control device shown in FIG. 1, and FIG. 3 is a side view of the first cover or the third cover shown in FIG. 2. As shown in FIGS. 2 and 3, a first support 204 is disposed on the cleaning chamber, a first through hole 205 is disposed in the first support 204, first strip hole 206 is disposed in the first cover 101, a first bolt 207 is disposed in the first strip hole 206, the first bolt 207 fixedly connects with the first through hole 205 so that the first cover 101 is fixed to the first support 204. The first strip hole 206 is used for fixing the first bolt 207 to different positions of the first strip hole 206 so as to adjust the height of the first cover 101. The numbers of the first strip hole 206, first through hole 205 and first bolt 207 are three respectively, the three first strip holes 206 are arranged parallel to each other. Certainly, the number of the strip hole in every cover can be more than three according to the size of the cleaning chamber. Each of the second cover 102, third cover 103 and fourth cover 104 has a similar structure as the first cover 101, so not mentioned here.

The covers should be adjusted with respect to various super high pressure, in order to ensure that the substrate would not be disturbed by the strong airflow during transfer process. Therefore, the strip hole is mainly used for adjusting the vertical height of the cover to change the gap value of the cover. From FIG. 3, it can be seen that, the side shape of the cover is an “L” shape, and the vertical bent portion in the “L” shape can be hold temporarily by hand in order to hold the cover and lock the bolt, so that manual adjustment of the gap value becomes easy. From FIG. 2, it can be seen that, a first graduated scale 302 is provided on both sides of the first cover 101. Certainly, graduated scales are also provided on other three covers. Since the four supports are stationary, the positions of the bolts on the graduated scales directly show the amount of vertical movement of the corresponding covers, thereby current gap value can be calculated accurately and conveniently later. By the graduated scales, the operator can read and record current gap value conveniently, to track, record and manage parameters in the process more conveniently.

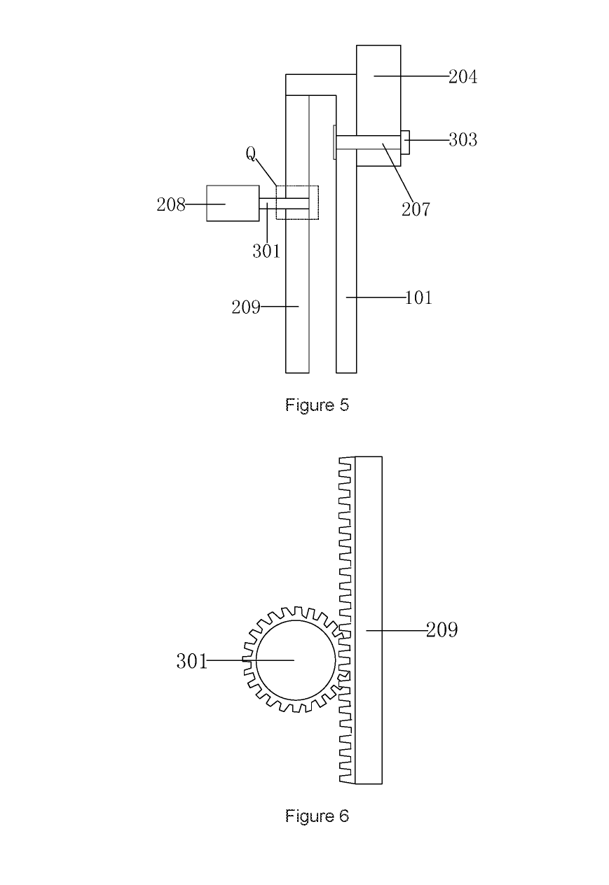

FIG. 4 is a front view of another first cover or third cover in the airflow control device shown in FIG. 1, FIG. 5 is a side view of the first cover or the third cover shown in FIG. 4, and FIG. 6 is an enlarged view of the structure of part Q shown in FIG. 5. As shown in FIGS. 4 to 6, the airflow control device further includes a first motor 208 and a first rack 209, the first motor 208 is fixedly disposed outside the cleaning chamber, the first rack 209 fixedly connects with the first cover 101, a gear matching with the first rack 209 is disposed on a rotary shaft 301 of the first motor 208 so as to drive the first rack 209 to move vertically. Each of the second cover 102, third cover 103 and fourth cover 104 has a similar structure as the first cover 101, so not mentioned here.

In this Example, since the motor is stationary, the amount of motor rotation can be converted to the amount of rack's vertical movement. The rack drives the cover to move vertically, thereby the automatic adjustment of the cover is achieved. Here, the first bolt 207 and a first nut 303 as shown in the figures are not locked tightly so that the cover is in the state of sliding freely. Compared to manual adjustment, automatic adjustment achieved by motor control can simplify adjusting process and increase adjusting accuracy.

Referring to FIG. 5, the motor is located outside the cleaning chamber, but the rotary shaft extends to the inside of the cleaning chamber, a gear is disposed on the rotary shaft, and the rack has teeth matching with the gear thereon. When the gear rotates clockwise, the rack drives the cover to move downward, when the gear rotates counterclockwise, the rack drives the cover to move upward.

In the airflow control device provided by the Example 1, the first cover and the third cover are disposed face to face in the upper portion of the cleaning chamber, and the second cover and the fourth cover are disposed face to face in the lower portion of the cleaning chamber, the first gap is formed between the first cover and the second cover, and the second gap is formed between the third cover and the fourth cover; the first cover, second cover, third cover and fourth cover form an airflow control space which accommodates a cleaning solution outlet, the airflow control space is used for keeping the strong airflow within the area under the cleaning solution outlet, thereby the shaking and deformation of the substrate due to the strong airflow are reduced, the effect of cleaning is improved, the risk of fragmentation is reduced, and thereby the production cost is reduced.

### Example 2

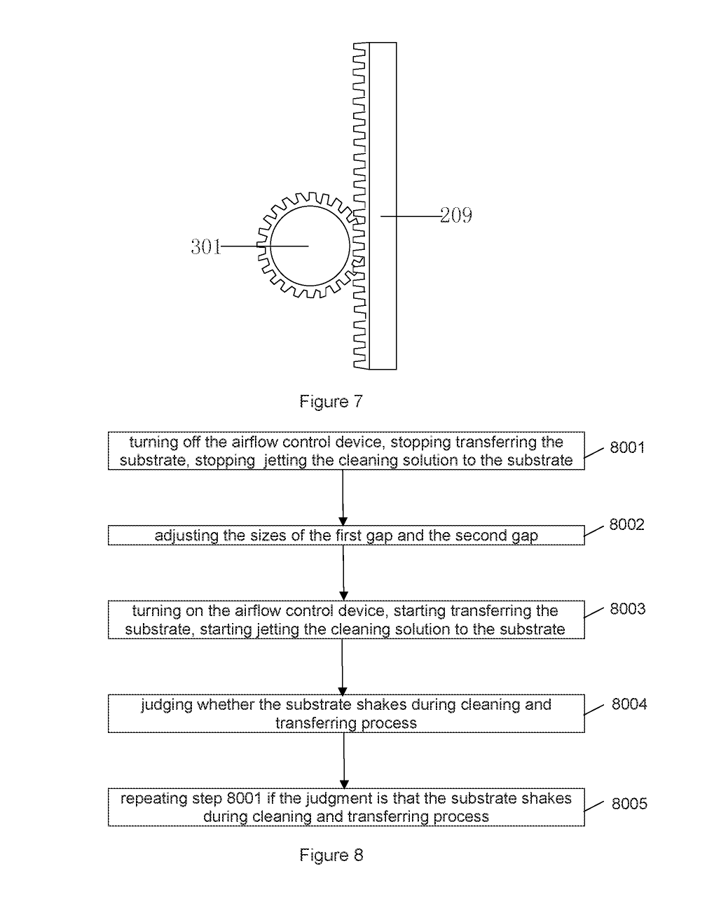

FIG. 7 is a schematic view of the structure of a substrate cleaning device provided in Example 2 of the present invention. As shown in FIG. 7, the substrate cleaning device includes a cleaning chamber and the airflow control device provided by Example 1. The airflow control device includes the first cover 101, the second cover 102, the third cover 103 and the fourth cover 104. The first cover 101 and the third cover 103 are disposed face to face in the upper portion of the cleaning chamber, the second cover 102 and the fourth cover 104 are disposed face to face in the lower portion of the cleaning chamber, so that the first cover 101, the second cover 102, the third cover 103 and the fourth cover 104 form an airflow control space which accommodates the cleaning solution outlet 105. The airflow control space is used for keeping the strong airflow within the area under the cleaning solution outlet, thereby the shaking and deformation of the substrate due to the strong airflow are reduced, the effect of cleaning is improved, the risk of fragmentation is reduced, and thereby the production cost is reduced. With respect to the specifics of the airflow control device, please refer to the description in Example 1 above, so not mentioned here.

Referring to FIG. 1, when the substrate 202 enters into the place just below the cleaning solution outlet 105 along the direction of arrow on the left side of FIG. 1 to super high pressure cleaning, the transfer wheel 106 is used for providing transferring power to the substrate 202, the first pinch roller (Double Roller) is used for clamping the substrate 202, and the second pinch roller (Double Roller) is used for clamping the substrate 202, too. The first pinch roller includes the first upper pinch roller 107 and the first lower pinch roller 108 disposed opposite to each other, the second pinch roller includes the second upper pinch roller 109 and the second lower pinch roller 201 disposed opposite to each other. The first pinch roller is disposed on one side of said airflow control space, and the second pinch roller is disposed on the other side of said airflow control space. The sensor 203 is disposed below the substrate 202, the sensor 203 is used for detecting shaking amplitude of the substrate 202, so that operator can know about the shaking all the time. When the substrate 202 shakes and deforms severely on the transfer wheel, even floats above the transfer wheel, the sensor 203 will glitter. The first pinch roller and the second pinch roller can reduce the shaking amplitude of substrate, avoid effectively the disturbance from the strong airflow during transfer process and the damage to the substrate itself, thereby the risk of fragmentation can be greatly reduced.

It should be emphasized that, the sizes of the first gap and the second gap directly decide flow rate and direction of the airflow spreading from the airflow control space. The first gap and the second gap should be adjusted with respect to various super high pressure, in order to ensure that the airflow spreading through the gaps would not affect the transfer of the substrate. The size of the first gap is referred to Gap A, the size of the second gap is referred to Gap B. In practical application and adjustment, the value of Gap A is not necessarily the same as the that of Gap B, that depends on actual conditions.

In this Example, the airflow control device further includes an exhaust structure 304, the exhaust structure 304 is connected with the airflow control space via a vent port, the vent port is disposed in the second cover or the fourth cover, the exhaust structure is used for reducing the pressure in the airflow control space.

In the substrate cleaning device provided by this Example, the first cover and the third cover are disposed face to face in the upper portion of the cleaning chamber, and the second cover and the fourth cover are disposed face to face in the lower portion of the cleaning chamber, the first gap is formed between the first cover and the second cover, and the second gap is formed between the third cover and the fourth cover; the first cover, second cover, third cover and fourth cover form an airflow control space which accommodates a cleaning solution outlet, the airflow control space is used for keeping the strong airflow within the area under the cleaning solution outlet, thereby the shaking and deformation of the substrate due to the strong airflow are reduced, the effect of cleaning is improved, the risk of fragmentation is reduced, and thereby the production cost is reduced.

### Example 3

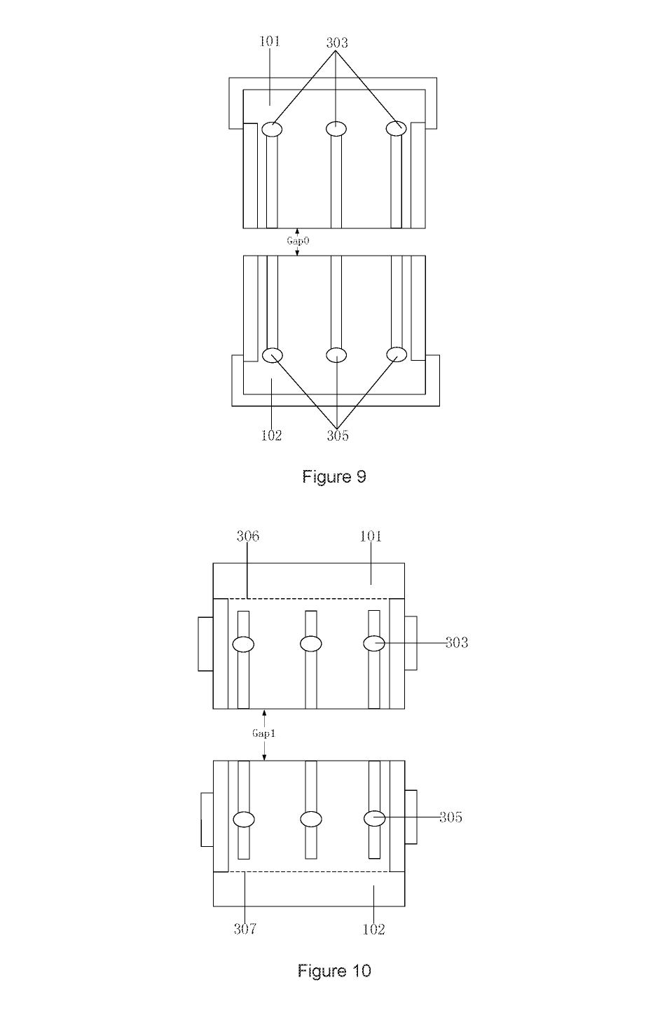

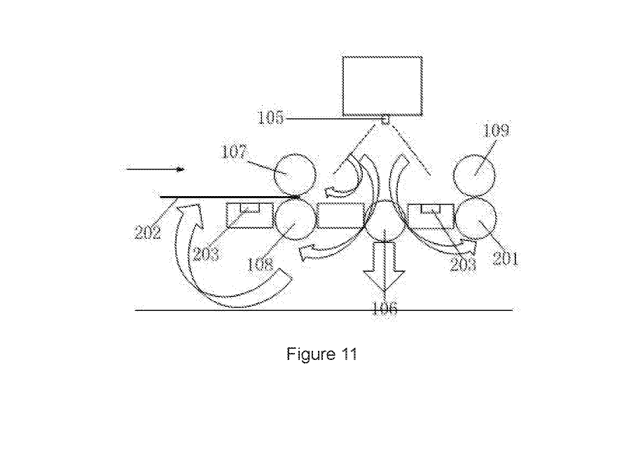

FIG. 8 is a flow chart of the method for adjusting an airflow control device provided in Example 3 of the present invention. As shown in FIG. 8, the airflow control device includes the first cover, the second cover, the third cover and the fourth cover. The first cover and the third cover are disposed face to face in the upper portion of the cleaning chamber, the second cover and the fourth cover are disposed face to face in the lower portion of the cleaning chamber, the first gap is formed between the first cover and the second cover, and the second gap is formed between the third cover and the fourth cover; the first cover, second cover, third cover and fourth cover form an airflow control space which accommodates a cleaning solution outlet.

The adjusting method includes:

step 8001, turning off the airflow control device, stopping transferring the substrate, stopping t jetting cleaning solution to the substrate.

In practical applications, firstly turn off the airflow control device of the cleaning chamber to stop transferring the substrate, and the cleaning solution outlet stops jetting the cleaning solution to the substrate, then open a protective cover of the cleaning chamber.

step 8002, adjusting the sizes of the first gap and the second gap.

Referring to FIGS. 2 and 3, the first support 204 is disposed in the cleaning chamber, the first through hole 205 is disposed in the first support 204, the first strip hole 206 is disposed in the first cover 101, the first bolt 207 is disposed in the first strip hole 206, the first bolt 207 fixedly connects with the first through hole 205 so that the first cover 101 is fixed to the first support 204. The first strip hole 206 is used for fixing the first bolt 207 to different positions of the first strip hole 206 so as to adjust the height of the first cover 101. The numbers of the first strip hole 206, first through hole 205 and first bolt 207 are three respectively, the three first strip hole 206 are arranged parallel to each other. In practical applications, the number of the first strip hole 206 can be more than three according to the size of the cleaning chamber. Each of the second cover 102, third cover 103 and fourth cover 104 has a similar structure as the first cover 101, so not mentioned here. In this Example, step 8002 includes: s18 adjusting the first bolt, second bolt, third bolt and fourth bolt so that the first cover, second cover, third cover and fourth cover can move vertically; moving the first cover, second cover, third cover and fourth cover to predetermined positions; adjusting the first bolt, second bolt, third bolt and fourth bolt to fix the first cover, second cover, third cover and fourth cover.

FIG. 9 is a structure diagram of the first cover and second cover, or the third cover and fourth cover in Example 3. As shown in FIG. 9, the bolt and nut 303 of the cover 101 is locked at the uppermost position, the uppermost position is defined as 0 line position of an upper graduated scale, the bolt and nut 305 of the cover 102 is locked at the lowermost position simultaneously, the lowermost position is defined as 0 line position of a lower graduated scale. Here, the initial gap value is recorded as Gap 0. Since the thickness of the substrate usually is 0.5 mm or 0.7 mm, it still shakes inevitably when undergoing super high pressure cleaning, Gap 0 is proposed to set to be ≧10 mm in view of safety concerns.

FIG. 10 is another structure diagram of the first cover and second cover, or the third cover and fourth cover in Example 3. As shown in FIG. 10, after adjusting the height position of the cover, there is a first height difference between the position of the bolt and nut 303 and the first graduated scale baseline 306, and a second height difference between the position of the bolt and nut 305 and first graduated scale baseline 307, both of which can be read on graduated scales on both sides of the covers. The first height difference is recorded as H1, the second height difference is recorded as H2, both H1 and H2 must be positive value. Here, gap value Gap1=Gap0+H1+H2. Assuming that Gap0 is 10 mm, H1 is 25 mm and H2 is 20 mm, gap value Gap1=55 mm.

Referring to FIGS. 4 to 6, the airflow control device further includes the first motor 208 and the first rack 209, the first motor 208 is fixedly disposed outside the cleaning chamber, the first rack 209 fixedly connects with the first cover 101, a gear matching with the first rack 209 is disposed on the rotary shaft 301 of the first motor 208 so as to drive the first rack 209 to move vertically. Each of the second cover 102, third cover 103 and fourth cover 104 has a similar structure as the first cover 101, so not mentioned here. In this Example, step 8002 includes: turning on the first motor, second motor, third motor and fourth motor; controlling the rotation direction and rotation amount of the first motor, second motor, third motor and fourth motor to move the first cover, second cover, third cover and fourth cover to predetermined positions; turning off the first motor, second motor, third motor and fourth motor.

In practical applications, since the motor is located in the middle part of the rack, in order to ensure the safety of the two, it is necessary to calibrate the amount of motor rotation and rack's vertical movement first. Rotate the motor clockwise, the rack will move downward, record the pulse value as Down 1 Limit when the rack reaches the limit position. Rotate the motor counterclockwise, the rack will move upward, record the pulse value as Up 1 Limit when the rack reaches the limit position. The other three motors and racks are calibrated in the same way, and Down 2 Limit and UP 2 Limit, Down 3 Limit and UP 3 Limit, Down 4 Limit and UP 4 Limit are obtained respectively. Finally, these four groups of limit positions are input into a software for controlling the motor. For example, in the case of adjusting the vertical movement of the first cover, when Down 1 Limit corresponds to pulse value of 1005 and UP 1 Limit corresponds to pulse value of 3025, the first cover will move to a position corresponding to a specified pulse as long as the pulse value input is in the range of 1005 to 3025. Observing the state of the substrate in cleaning and transferring under the current pulse, if the substrate shakes and deforms severely, the operator may continuously repeat inputting pulse values in the range of 1005 to 3025 according to the need of adjustment, until the transfer of the substrate becomes normal.

step 8003, turning on the airflow control device, starting transferring the substrate, starting jetting the cleaning solution to the substrate.

In practical applications, first close the protective cover of the cleaning chamber in order to prevent splashing of water, then turn on the airflow control device of the cleaning chamber to start transferring the substrate, and start jetting the cleaning solution to the substrate.

step 8004, judging whether the substrate shakes during cleaning and transferring process.

step 8005, repeating step 8001 if the judgment is that the substrate shakes during cleaning and transferring process.

Referring to FIG. 7, the airflow control device further includes the exhaust structure 304, the exhaust structure 304 is connected with the airflow control space via the vent port, the vent port is disposed in the second cover or the fourth cover. The exhaust structure 304 is used for reducing the pressure in the airflow control space. In the case the problem cannot be solved by adjusting the covers, open the attached exhaust structure. At this moment, the gap of the cover has a minimum value. Open the valve of the exhaust structure, and observe the state of the substrate in cleaning and transferring. If the substrate shakes and deforms severely, increase exhaust volume of the valve. And then go observing the state of the substrate in cleaning and transferring, if the substrate still shakes and deforms severely, the operator may continuously repeat increasing exhaust volume of the valve, until the transfer of the substrate becomes normal.

In the method for adjusting an airflow control device provided by this Example, the first cover and the third cover are disposed face to face in the upper portion of the cleaning chamber, and the second cover and the fourth cover are disposed face to face in the lower portion of the cleaning chamber, that the first gap is formed between the first cover and the second cover, and the second gap is formed between the third cover and the fourth cover; the first cover, second cover, third cover and fourth cover form an airflow control space which accommodates a cleaning solution outlet, the airflow control space is used for keeping the strong airflow within the area under the cleaning solution outlet, thereby the shaking and deformation of the substrate due to the strong airflow are reduced, the effect of cleaning is improved, the risk of fragmentation is reduced, and thereby the production cost is reduced.

It should be understood that the above embodiments of the invention have been described only for illustrating the principle of the present invention, but not intended to limit the present invention. The person skilled in the art can make various modifications and variations of the invention without departing from the spirit and scope of the invention, thus the modifications and variations of the invention are also included within the scope of the present invention.

1. An airflow control device disposed in a cleaning chamber for cleaning a substrate, characterized in that,
said airflow control device includes a first cover, a second cover, a third cover and a fourth cover; said first cover and said third cover are disposed face to face in the upper portion of the cleaning chamber, and said second cover and said fourth cover are disposed face to face in the lower portion of the cleaning chamber, a first gap is formed between said first cover and said second cover, and a second gap is formed between said third cover and said fourth cover; said first cover, said second cover, said third cover and said fourth cover form an airflow control space which accommodates a cleaning solution outlet,
said substrate enters into the airflow control space through said first gap, and leaves the airflow control space through said second gap.

2. The airflow control device according to claim 1, wherein,
said first cover, said second cover, said third cover and said fourth cover are substantially perpendicular to the transfer direction of the substrate.

3. The airflow control device according to claim 1, wherein,
it further includes an exhaust structure, said exhaust structure is connected with said airflow control space via a vent port, said vent port is disposed in said second cover or said fourth cover;
said exhaust structure is used for reducing the pressure in said airflow control space.

4. The airflow control device according to claim 1, wherein,
a first support is disposed on said cleaning chamber, a first through hole is disposed in said first support, a first strip hole is disposed in said first cover, a first bolt is disposed in said first strip hole, said first bolt fixedly connects with said first through hole so that said first cover is fixed to said first support, said first strip hole is used for fixing said first bolt to different positions of said first strip hole so as to adjust the height of said first cover;
a second support is disposed on said cleaning chamber, a second through hole is disposed in said second support, a second strip hole is disposed in said second cover, a second bolt is disposed in said second strip hole, said second bolt fixedly connects with said second through hole so that said second cover is fixed to said second support, said second strip hole is used for fixing said second bolt to different positions of said second strip hole so as to adjust the height of said second cover;
a third support is disposed on said cleaning chamber, a third through hole is disposed in said third support, a third strip hole is disposed in said third cover, a third bolt is disposed in said third strip hole, said third bolt fixedly connects with said third through hole so that said third cover is fixed to said third support, said third strip hole is used for fixing said third bolt to different positions of said third strip hole so as to adjust the height of said third cover;
a fourth support is disposed on top of said cleaning chamber, a fourth through hole is disposed in said fourth support, a fourth strip hole is disposed in said fourth cover, a fourth bolt is disposed in said fourth strip hole, said fourth bolt fixedly connects with said fourth through hole so that said fourth cover is fixed to said fourth support, said fourth strip hole is used for fixing said fourth bolt to different positions of said fourth strip hole so as to adjust the height of said fourth cover.

5. The airflow control device according to claim 4, wherein,
the numbers of said first strip hole, first through hole and first bolt are three respectively, said three first strip holes are arranged parallel to each other;
the numbers of said second strip hole, second through hole and second bolt are three respectively, said three second strip holes are arranged parallel to each other;
the numbers of said third strip hole, third through hole and third bolt are respectively three, said three third strip holes are arranged parallel to each other;
the numbers of said fourth strip hole, fourth through hole and fourth bolt are respectively three, said three fourth strip holes are arranged parallel to each other.

6. The airflow control device according to claim 4, wherein,
it further includes a first motor, a first rack, a second motor, a second rack, a third motor, a third rack, a fourth motor and a fourth rack,
said first motor is fixedly disposed outside said cleaning chamber, said first rack fixedly connects with said first cover, a gear matching with said first rack is disposed on the rotary shaft of said first motor so as to drive said first rack to move vertically;
said second motor is fixedly disposed outside said cleaning chamber, said second rack fixedly connects with said second cover, a gear matching with said second rack is disposed on the rotary shaft of said second motor so as to drive said second rack to move vertically;
said third motor is fixedly disposed outside said cleaning chamber, said third rack fixedly connects with said third cover, a gear matching with said third rack is disposed on the rotary shaft of said third motor so as to drive said third rack to move vertically;
said fourth motor is fixedly disposed outside said cleaning chamber, said fourth rack fixedly connects with said fourth cover, a gear matching with said fourth rack is disposed on the rotary shaft of said fourth motor so as to drive said fourth rack to move vertically.

7. The airflow control device according to claim 4, wherein,
accurate graduated scales are amounted on both sides of said covers.

8. The airflow control device according to claim 7, wherein, the size of the gap is calculated as follow:
Cover GAP=Gap0+H1+H2
wherein, Cover GAP represents the size of the gap, Gap0 represents the size of the gap when the bolt of the cover above the substrate is fixed at the uppermost position of a corresponding strip hole, and the size of the gap when the bolt of the cover below the substrate is locked at the lowermost position of a corresponding strip hole, H1 represents a height difference between the position of the bolt in the cover above the substrate after adjusting the cover and the uppermost position of the bolt, H2 represents a height difference between the position of the bolt in the cover below the substrate after adjusting the cover and the lowermost position of the bolt.

9. The airflow control device according to claim 1, wherein,
the size of said first gap is not less than 10 mm, the size of said second gap is not less than 10 mm.

10. The airflow control device according to claim 9, wherein,
the distance between said first cover and the substrate plane is 1 cm-10 cm,
the distance between said second cover and the substrate plane is 1 cm-10 cm,
the distance between said third cover and the substrate plane is 1 cm-10 cm,
the distance between said fourth cover and the substrate plane is 1 cm-10 cm.

11. A substrate cleaning device, characterized in that, it includes a cleaning chamber and the airflow control device according to claim 1.

12. The substrate cleaning device according to claim 11, wherein,
it further includes a transfer wheel, a first pinch roller and a second pinch roller, said first pinch roller includes a first upper pinch roller and a first lower pinch roller disposed opposite to each other, said second pinch roller includes a second upper pinch roller and a second lower pinch roller disposed opposite to each other said first pinch roller is disposed on one side of said airflow control space, said second pinch roller is disposed on the other side of said airflow control space; when driven by the transfer wheel, said substrate enters into the airflow control space through the gap between said first upper pinch roller and said first lower pinch roller, and then leaves the airflow control space through the gap between said second upper pinch roller and said second lower pinch roller;
said transfer wheel is used for providing transferring power to said substrate;
said first pinch roller is used for clamping said substrate;
said second pinch roller is used for clamping said substrate.

13. A method of adjusting an airflow control device, which is used on the airflow control device according to claim 1, the method includes:
turning off said airflow control device, stopping transferring the substrate, stopping jetting cleaning solution to said substrate;
adjusting the sizes of said first gap and said second gap;
turning on said airflow control device, starting transferring the substrate, starting jetting cleaning solution to said substrate;
judging whether said substrate shakes during cleaning and transferring process;
repeating said step of turning off said airflow control device if the judgment is that said substrate shakes during cleaning and transferring process.

14. The method of adjusting an airflow control device according to claim 13, wherein,
a first support is disposed on top of said cleaning chamber, a first through hole is disposed in said first support, a first strip hole is disposed in said first cover, a first bolt is disposed in said first strip hole, said first bolt fixedly connects with said first through hole so that said first cover is fixed to said first support, said first strip hole is used for fixing said first bolt to different positions of said first strip hole so as to adjust the height of said first cover;
a second support is disposed on top of said cleaning chamber, a second through hole is disposed in said second support, a second strip hole is disposed in said second cover, a second bolt is disposed in said second strip hole, said second bolt fixedly connects with said second through hole so that said second cover is fixed to said second support, said second strip hole is used for fixing said second bolt to different positions of said second strip hole so as to adjust the height of said second cover;
a third support is disposed on top of said cleaning chamber, a third through hole is disposed in said third support, a third strip hole is disposed in said third cover, a third bolt is disposed in said third strip hole, said third bolt fixedly connects with said third through hole so that said third cover is fixed to said third support, said third strip hole is used for fixing said third bolt to different positions of said third strip hole so as to adjust the height of said third cover;
a fourth support is disposed on top of said cleaning chamber, a fourth through hole is disposed in said fourth support, a fourth strip hole is disposed in said fourth cover, a fourth bolt is disposed in said fourth strip hole, said fourth bolt fixedly connects with said fourth through hole so that said fourth cover is fixed to said fourth support, said fourth strip hole is used for fixing said fourth bolt to different positions of said fourth strip hole so as to adjust the height of said fourth cover;
the step of adjusting the sizes of said first gap and said second gap includes:
adjusting said first bolt, said second bolt, said third bolt and said fourth bolt so that said first cover, said second cover, said third cover and said fourth cover can move vertically;
moving said first cover, said second cover, said third cover and said fourth cover to predetermined positions;
adjusting said first bolt, said second bolt, said third bolt and said fourth bolt to fix said first cover, said second cover, said third cover and said fourth cover.

15. The method of adjusting an airflow control device according to claim 13, wherein, said airflow control device further includes a first motor, a first rack, a second motor, a second rack, a third motor, a third rack, a fourth motor and a fourth rack;
said first motor is fixedly disposed outside said cleaning chamber, said first rack fixedly connects with said first cover, a gear matching with said first rack is disposed on the rotary shaft of said first motor so as to drive said first rack to move vertically;
said second motor is fixedly disposed outside said cleaning chamber, said second rack fixedly connects with said second cover, a gear matching with said second rack is disposed on the rotary shaft of said second motor so as to drive said second rack to move vertically;
said third motor is fixedly disposed outside said cleaning chamber, said third rack fixedly connects with said third cover, a gear matching with said third rack is disposed on the rotary shaft of said third motor so as to drive said third rack to move vertically;
said fourth motor is fixedly disposed outside said cleaning chamber, said fourth rack fixedly connects with said fourth cover, a gear matching with said fourth rack is disposed on the rotary shaft of said fourth motor so as to drive said fourth rack to move vertically;
the step of adjusting the sizes of said first gap and said second gap includes:
turning on said first motor, said second motor, said third motor and said fourth motor;
controlling the rotation direction and rotation amount of said first motor, said second motor, said third motor and said fourth motor to move said first cover, said second cover, said third cover and said fourth cover to predetermined positions;
turning off said first motor, said second motor, said third motor and said fourth motor.

16. The method of adjusting an airflow control device according to claim 13, wherein, said airflow control device further includes an exhaust structure, said exhaust structure is connected with said airflow control space via a vent port, said vent port is disposed in said second cover or said fourth cover;
the adjusting method further includes:
turning on said exhaust structure if it is judged that said substrate shakes during cleaning and transferring process when the sizes of said first gap and said second gap are adjusted to a minimum value;
controlling said exhaust structure to reduce the pressure in said airflow control space in a predetermined exhaust amount;
judging whether said substrate shakes during cleaning and transferring process; repeating said step of controlling said exhaust structure reducing the pressure in said airflow control space with a predetermined exhaust amount if the judgment is that said substrate shakes during cleaning and transferring process.
